(19) United States
(12) Patent Application Publication
(10) Pub. No.: US 2025/0096019 A1
(43) Pub. Date: Mar. 20, 2025

(54) SUBSTRATE PROCESSING SYSTEMS AND METHODS USING VIRTUAL MACHINE ARCHITECTURE FOR OPERATING SUBSTRATE PROCESSING CHAMBERS

(71) Applicant: ASM IP Holding B.V., Almere (NL)

(72) Inventor: Eric Steinseifer, Tempe, AZ (US)

(21) Appl. No.: 18/884,434

(22) Filed: Sep. 13, 2024

Related U.S. Application Data
(60) Provisional application No. 63/538,606, filed on Sep. 15, 2023.

(51) Int. Cl. H01L 21/67; G05B 19/418; H01L 21/687

(52) U.S. Cl. CPC H01L 21/67167; G05B 19/4189; H01L 21/68707; G05B 2219/39001; G05B 2219/45031

(57) ABSTRACT

Substrate processing systems and methods include functions of the substrate processing chambers virtually controlled by process module software for the individual substrate processing chambers operating on a remote platform computer (e.g., located with the equipment front end module or load-lock module). The platform computer includes memory storing process module software for each of the associated substrate processing chambers and transmits signals for operating those substrate processing chambers based on data generated by the respective process module software for that substrate processing chamber. The platform computer also receives data transmitted from the substrate processing chambers (e.g., sensor data) that may be used by their respective process module software for generating further operating signals for controlling the respective substrate processing chamber. Avoiding the use and/or inclusion of separate computers in and associated with each individual substrate processing chamber can simplify maintenance and repair, reduce costs, reduce downtime, and improve efficiency.

### CROSS-REFERENCE TO RELATED APPLICATION(S)

This application claims the benefit of U.S. Provisional Application 63/538,606 filed on Sep. 15, 2023, the entire contents of which are incorporated herein by reference.

### FIELD OF THE DISCLOSURE

The present disclosure relates generally to substrate processing systems and methods in which functions of the substrate processing chambers are virtually controlled by software operating on a remote platform computer. In this manner, separate personal computers (“PCs”) for operating the substrate processing chambers can be eliminated.

### BACKGROUND OF THE DISCLOSURE

Material layers are commonly deposited onto substrates during fabrication of semiconductor devices, such as during fabrication of integrated circuits and electronic devices. Material layer deposition generally is accomplished by supporting a substrate within a substrate processing chamber arrangement, heating the substrate to a desired deposition temperature, and flowing one or more material layer precursors through the chamber arrangement and across the substrate. As the precursor flows across the substrate, the material layer progressively develops onto the surface of the substrate, typically according to the temperature of the substrate and environmental conditions within the chamber arrangement.

Existing substrate processing systems 10 include “cluster type” systems of the type generally shown in FIG. 1A. Such substrate processing systems 10 include a substrate handling chamber 12 that operatively connects with two to four substrate processing chambers 14A-14D via gate valves 16. Each substrate processing chamber 14A-14D is equipped to receive a substrate on a substrate support 18 that holds the substrate during processing (e.g., during material layer deposition as described above).

The substrate handling chamber 12 includes robotic arm 20 used to move substrates into and out of the various substrate processing chambers 14A-14D through the gate valves 16. In use, a gate valve 16 is opened, an end effector 20A of the robotic arm 20 extends through the open gate valve 16 to insert a substrate into or remove a substrate from an interior chamber of the substrate processing chamber 14A-14D (e.g., placing a substrate on or taking a substrate off the substrate support 18). Once the robotic arm 20 is retracted from the substrate processing chamber 14A-14D, the gate valve 16 is closed, thereby sealing the substrate processing chamber 14A-14D from the substrate handling chamber 12. Then, other desired actions can take place in the substrate processing chamber 14A-14D and/or the substrate handling chamber 12.

FIG. 1A further shows that this substrate processing system 10 includes a load-lock module 22. The load-lock module 22 is connected with the substrate handling chamber 12 by gate valves 24. The load-lock module 22 includes one or more substrate holding components 22A for holding substrates on the way into the substrate handling chamber 12 for further processing and on the way out of the substrate handling chamber 12 (after processing is complete). The end effector 20A of robotic arm 20 moves through gate valve 24 (when opened) to move substrates from the load-lock module 22 into the substrate handling chamber 12 (for layer deposition and other processing in substrate processing chambers 14A-14D) and from the substrate handling chamber 12 into the load-lock module 22 (after processing is completed). The load-lock module 22 and gate valves 24 keep the substrates isolated from the environment of the substrate handling chamber 12 until the conditions (e.g., temperature, pressure, content of atmosphere, etc.) within the substrate handling chamber 12 and the load-lock module 22 are ready for the substrate(s) to be transferred.

The load-lock module 22 further is coupled with an equipment front end module 26 via one or more additional gate valves 28. The equipment front end module 26 includes a robotic arm 30. The end effector 30A of that robotic arm 30 moves through the gate valve 28 (when opened) to move substrates from the equipment front end module 26 into the load-lock module 22 (for layer deposition and other processing) and from the load-lock module 22 into the equipment front end module 26 (after processing is completed). The robotic arm 30 of the equipment front end module 26 also picks up new substrates for processing from one of the load ports 32A-32D and returns processed substrates to one of the load ports 32A-32D, e.g., to be transported to another location for further processing.

Substrate processing systems 10 of the types described above are equipped with several computers. In conventional arrangements, as shown in FIGS. 1A-1C, a platform computer 40 is in communication with separate, dedicated computers 42A-42D provided in each of the substrate processing chambers 14A-14D. The separate, dedicated computers 42A-42D operate their respective substrate processing chamber 14A-14D (with one separate and dedicated computer 42A-42D provided per substrate processing chamber 14A-14D, respectively). These separate, dedicated computers 42A-42D provided in each of the individual substrate processing chambers 14A-14D may constitute complete PC's, each with its own operating system, memory, etc. The platform computer 40 may be connected to input/output ports 44A-44D of the computers 42A-42D provided with each of the substrate processing chambers 14A-14D by an Ethernet cable 46A-46D. As shown in FIGS. 1A-1C, data from the platform computer 40 is transmitted to the various computers 42A-42D provided with the substrate processing chambers 14A-14D. These computers 42A-42D, using software 48A-48D stored in their local memory, are configured to: (a) process incoming data from the platform computer 40, (b) process incoming data from equipment associated with that substrate processing chamber 14A-14D (e.g., pressure sensor(s) 50, temperature sensor(s) 52, one or more motors 54, one or more heating elements 56, etc.), (c) generate and transmit data sending signals to run the equipment associated with that substrate processing chamber 14A-14D (e.g., pressure sensor 50, temperature sensor 52, motor(s) 54, heating element(s) 56, etc.), and (d) generate and transmit data back to the platform computer 40. The platform computer 40 receives incoming data from the substrate processing chambers 14A-14D (and other sources) and uses that data to synchronize and control operation of the overall substrate processing system 10.

Conventional semiconductor production systems and methods of this type generally have been acceptable for their intended purpose, but there is room for improvement. For example, this distributed computing architecture (with separate and dedicated computers 42A-42D in each substrate processing chamber 14A-14D) add significant cost and complexity to substrate processing system 10. As some more specific examples, each computer 42A-42D of a corresponding substrate processing chamber 14A-14D requires its own operating system, its own virus scan software, and its own application software to cooperate with the platform computer 40. These features add significant costs and maintenance requirements to the substrate processing system 10. For example, software updates and maintenance add costs associated with the purchase/licensing price of updated software (for each computer 42A-42D); the labor costs involved with making the updates and/or maintenance (for each computer 42A-42D); and production “downtime” (if the substrate processing chamber 14A-14D has to be shut down for the computer updates/maintenance). Production downtime can add significant time delays and monetary costs, particularly if the substrate processing module 14A-14D has to be shut down and/or cooled for the update and maintenance processes, and then recalibrated, requalified, and/or heated up prior to resuming production.

The substrate processing chamber 14A-14D computers 42A-42D also take up space within and/or around the substrate processing chamber 14A-14D and require additional provisioning (e.g., power requirements, fans for cooling, user interface equipment, etc.). These features further complicate packaging of substrate processing system 10 and its components and further increase costs.

Improvements that reduce software costs, reduce processing downtime, and/or improve efficiency would be welcome advances in the art.

### SUMMARY OF THE DISCLOSURE

Aspects of this technology relate to substrate processing systems and methods in which functions of the substrate processing chambers are virtually controlled by process module software for the individual substrate processing chambers operating on a remote platform computer. These aspects of the present technology can avoid the use and/or inclusion of separate personal computers in and associated with each substrate processing chambers, thereby simplifying maintenance and repair, reducing costs, reducing downtime, and improving efficiency.

Substrate processing systems in accordance with at least some examples of this technology include one or more of: (a) a first substrate handling chamber including a first robotic arm; (b) a first substrate processing chamber coupled with the first substrate handling chamber via a first gate valve, wherein a portion of the first robotic arm is configured to extend through the first gate valve and into the first substrate processing chamber to move substrates into and out of the first substrate processing chamber; (c) a second substrate processing chamber coupled with the first substrate handling chamber via a second gate valve, wherein the portion of the first robotic arm is configured to extend through the second gate valve and into the second substrate processing chamber to move substrates into and out of the second substrate processing chamber; and (d) a platform computer located remote from and in electronic communication with the first substrate processing chamber and the second substrate processing chamber. The platform computer: (a) includes memory storing first process module software for operating the first substrate processing chamber and second process module software for operating the second substrate processing chamber, (b) transmits signals for operating the first substrate processing chamber based on data generated by the first process module software, and (c) transmits signals for operating the second substrate processing chamber based on data generated by the second process module software.

In addition to one or more of the features described above, or as an alternative, substrate processing systems in accordance with some examples of this technology may further comprise a third substrate processing chamber coupled with the first substrate handling chamber via a third gate valve, wherein the portion of the first robotic arm is configured to extend through the third gate valve and into the third substrate processing chamber to move substrates into and out of the third substrate processing chamber, wherein the platform computer is located remote from and in electronic communication with the third substrate processing chamber, wherein the memory of the platform computer further stores third process module software for operating the third substrate processing chamber, and wherein the platform computer further transmits signals for operating the third substrate processing chamber based on data generated by the third process module software.

In addition to one or more of the features described above, or as an alternative, substrate processing systems in accordance with some examples of this technology may further comprise a fourth substrate processing chamber coupled with the first substrate handling chamber via a fourth gate valve, wherein the portion of the first robotic arm is configured to extend through the fourth gate valve and into the fourth substrate processing chamber to move substrates into and out of the fourth substrate processing chamber, wherein the platform computer is located remote from and in electronic communication with the fourth substrate processing chamber, wherein the memory of the platform computer further stores fourth process module software for operating the fourth substrate processing chamber, and wherein the platform computer further transmits signals for operating the fourth substrate processing chamber based on data generated by the fourth process module software.

In addition to one or more of the features described above, or as an alternative, substrate processing systems in accordance with some examples of this technology may further comprise: (A) a second substrate handling chamber including a second robotic arm; and (B) a fifth substrate processing chamber coupled with the second substrate handling chamber via a fifth gate valve, wherein a portion of the second robotic arm is configured to extend through the fifth gate valve and into the fifth substrate processing chamber to move substrates into and out of the fifth substrate processing chamber, wherein the platform computer is located remote from and in electronic communication with the fifth substrate processing chamber, wherein the memory of the platform computer further stores fifth process module software for operating the fifth substrate processing chamber, and wherein the platform computer further transmits signals for operating the fifth substrate processing chamber based on data generated by the fifth process module software.

In addition to one or more of the features described above, or as an alternative, substrate processing systems in accordance with some examples of this technology may further comprise a sixth substrate processing chamber coupled with the second substrate handling chamber via a sixth gate valve, wherein the portion of the second robotic arm is configured to extend through the sixth gate valve and into the sixth substrate processing chamber to move substrates into and out of the sixth substrate processing chamber, wherein the platform computer is located remote from and in electronic communication with the sixth substrate processing chamber, wherein the memory of the platform computer further stores sixth process module software for operating the sixth substrate processing chamber, and wherein the platform computer further transmits signals for operating the sixth substrate processing chamber based on data generated by the sixth process module software.

In addition to one or more of the features described above, or as an alternative, substrate processing systems in accordance with some examples of this technology may further comprise a load lock module connecting the first substrate handling chamber and the second substrate handling chamber, wherein the load lock module is configured to hold substrates moving between the first substrate handling chamber and the second substrate handling chamber.

In addition to one or more of the features described above, or as an alternative, substrate processing systems in accordance with some examples of this technology may further comprise: (A) a second substrate handling chamber including a second robotic arm; and (B) a third substrate processing chamber coupled with the second substrate handling chamber via a third gate valve, wherein a portion of the second robotic arm is configured to extend through the third gate valve and into the third substrate processing chamber to move substrates into and out of the third substrate processing chamber, wherein the platform computer is located remote from and in electronic communication with the third substrate processing chamber, wherein the memory of the platform computer further stores third process module software for operating the third substrate processing chamber, and wherein the platform computer further transmits signals for operating the third substrate processing chamber based on data generated by the third process module software.

In addition to one or more of the features described above, or as an alternative, substrate processing systems in accordance with some examples of this technology may further comprise a load lock module connecting the first substrate handling chamber and the second substrate handling chamber, wherein the load lock module is configured to hold substrates moving between the first substrate handling chamber and the second substrate handling chamber.

Substrate processing systems in accordance with at least some examples of this technology include one or more of: (a) a first substrate handling chamber including a first robotic arm; (b) a first substrate processing chamber coupled with the first substrate handling chamber via a first gate valve, wherein a portion of the first robotic arm is configured to extend through the first gate valve and into the first substrate processing chamber to move substrates into and out of the first substrate processing chamber; (c) a second substrate processing chamber coupled with the first substrate handling chamber via a second gate valve, wherein the portion of the first robotic arm is configured to extend through the second gate valve and into the second substrate processing chamber to move substrates into and out of the second substrate processing chamber; (d) a front end module configured to receive unprocessed substrates for processing and to hold processed substrates prior to removal from the substrate processing system; (e) a first load lock module connecting the front end module and the first substrate handling chamber, wherein the first load lock module is configured to hold substrates moving between the front end module and the first substrate handling chamber; and (f) a platform computer provided with the front end module or the first load lock module, the platform computer being located remote from and in electronic communication with the first substrate processing chamber and the second substrate processing chamber. The platform computer: (a) includes memory storing first process module software for operating the first substrate processing chamber and second process module software for operating the second substrate processing chamber, (b) transmits signals for operating the first substrate processing chamber based on data generated by the first process module software, and (c) transmits signals for operating the second substrate processing chamber based on data generated by the second process module software.

In addition to one or more of the features described above, or as an alternative, substrate processing systems in accordance with some examples of this technology may further comprise: (A) a second substrate handling chamber including a second robotic arm; (B) a second load lock module connecting the first substrate handling chamber and the second substrate handling chamber, wherein the second load lock module is configured to hold substrates moving between the first substrate handling chamber and the second substrate handling chamber; and (C) a third substrate processing chamber coupled with the second substrate handling chamber via a third gate valve, wherein a portion of the second robotic arm is configured to extend through the third gate valve and into the third substrate processing chamber to move substrates into and out of the third substrate processing chamber, wherein the platform computer is located remote from and in electronic communication with the third substrate processing chamber, wherein the memory of the platform computer further stores third process module software for operating the third substrate processing chamber, and wherein the platform computer further transmits signals for operating the third substrate processing chamber based on data generated by the third process module software.

In addition to one or more of the features described above, or as an alternative, substrate processing systems in accordance with some examples of this technology may further comprise: (A) a second substrate handling chamber including a second robotic arm; (B) a second load lock module connecting the first substrate handling chamber and the second substrate handling chamber, wherein the second load lock module is configured to hold substrates moving between the first substrate handling chamber and the second substrate handling chamber; and (C) a plurality of additional substrate processing chambers coupled with the second substrate handling chamber, wherein a portion of the second robotic arm is configured to extend into the plurality of additional substrate processing chambers to move substrates into and out of the plurality of additional substrate processing chambers, wherein the platform computer is located remote from and in electronic communication with the plurality of additional substrate processing chambers, wherein the memory of the platform computer further stores process module software for operating each of the plurality of additional substrate processing chambers, and wherein the platform computer further transmits signals for operating the plurality of additional substrate processing chambers based on data generated by the process module software for the plurality of additional substrate processing chambers.

In addition to one or more of the features described above, or as an alternative, substrate processing systems in accordance with some examples of this technology may further comprise: (A) a second substrate handling chamber including a second robotic arm; (B) a second load lock module connecting the first substrate handling chamber and the second substrate handling chamber, wherein the second load lock module is configured to hold substrates moving between the first substrate handling chamber and the second substrate handling chamber; and (C) a plurality of additional substrate processing chambers coupled with the second substrate handling chamber, wherein a portion of the second robotic arm is configured to extend into the plurality of additional substrate processing chambers to move substrates into and out of the plurality of additional substrate processing chambers, wherein the platform computer is located remote from and in electronic communication with the plurality of additional substrate processing chambers, wherein the memory of the platform computer further stores separate process module software for operating each of the plurality of additional substrate processing chambers, and wherein the platform computer further transmits signals for operating the plurality of additional substrate processing chambers based on data generated by the process module software for the respective plurality of additional substrate processing chambers.

In addition to one or more of the features described above, or as an alternative, substrate processing systems in accordance with some examples of this technology may further comprise a plurality of additional substrate processing chambers coupled with the first substrate handling chamber, wherein the portion of the first robotic arm is configured to extend into the plurality of additional substrate processing chambers to move substrates into and out of the plurality of additional substrate processing chambers, wherein the platform computer is located remote from and in electronic communication with the plurality of additional substrate processing chambers, wherein the memory of the platform computer further stores process module software for operating each of the plurality of additional substrate processing chambers, and wherein the platform computer further transmits signals for operating the plurality of additional substrate processing chambers based on data generated by the process module software for the respective plurality of additional substrate processing chambers.

Methods of operating substrate processing systems in accordance with some examples of this technology may comprise one or more of: (a) operating a first substrate processing chamber using first operating instructions generated by first process module software stored in memory on a platform computer located remote from and in electronic communication with the first substrate processing chamber; (b) operating a second substrate processing chamber using second operating instructions generated by second process module software stored in the memory on the platform computer located remote from and in electronic communication with the second substrate processing chamber; (c) creating first replacement process module software; (d) storing the first replacement process module software in the memory of the platform computer; (e) replacing the first process module software with the first replacement process module software; and (f) operating the first substrate processing chamber using operating instructions generated by the first replacement process module software stored in the memory on the platform computer.

In addition to one or more of the features described above, or as an alternative, methods in accordance with some examples of this technology may further comprise one or more of: (A) creating second replacement process module software; (B) storing the second replacement process module software in the memory of the platform computer; (C) replacing the second process module software with the second replacement process module software; and (D) operating the second substrate processing chamber using operating instructions generated by the second replacement process module software stored in the memory on the platform computer.

In addition to one or more of the features described above, or as an alternative, methods in accordance with some examples of this technology may further comprise one or more of: (A) creating second replacement process module software; (B) storing the second replacement process module software in the memory of the platform computer; (C) replacing the first replacement process module software with the second replacement process module software; and (D) operating the first substrate processing chamber using operating instructions generated by the second replacement process module software stored in the memory on the platform computer.

In addition to one or more of the features described above, or as an alternative, in at least some examples of this technology, the step of replacing the first process module software with the first replacement process module software occurs while the first substrate processing chamber is processing one or more substrates and without interrupting processing of the one or more substrates.

In addition to one or more of the features described above, or as an alternative, in at least some examples of this technology, the step of replacing the first process module software with the first replacement process module software occurs without shutting down operation of the first substrate processing chamber.

In addition to one or more of the features described above, or as an alternative, in at least some examples of this technology, the first replacement process module software comprises a software upgrade from the first process module software.

In addition to one or more of the features described above, or as an alternative, methods in accordance with some examples of this technology may further comprise one or more of: (A) operating one or more additional substrate processing chambers using additional operating instructions generated by one or more additional process module software components stored in the memory on the platform computer located remote from and in electronic communication with the one or more additional substrate processing chambers; (B) creating an additional replacement process module software component; (C) storing the additional replacement process module software component in the memory of the platform computer; (D) replacing one of the additional process module software components with the additional replacement process module software component; and (E) operating a specific additional substrate processing chamber associated with the additional process module software component that was replaced by the additional replacement process module software component using operating instructions generated by the additional replacement process module software component stored in the memory on the platform computer. One or more of these steps may take place without interrupting processing of substrates and/or without shutting down operation of any of the substrate processing chambers.

This Summary is provided to introduce a selection of concepts relating to this technology in a simplified form. These concepts are described in further detail in the Detailed Description below. This Summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIGS. 1A-1C show various views of conventional cluster type substrate processing systems having separate, dedicated computers for each substrate processing chamber;

FIGS. 2A-2C show various views of cluster type substrate processing systems and methods in accordance with aspects of this technology including virtual control of substrate processing chambers from the platform computer;

FIGS. 3A and 3B illustrate features of replacing software components for operating substrate processing chambers at the platform computer level in substrate processing systems and methods in accordance with aspects of this technology;

FIG. 4 generically illustrates equipment and connection of a platform computer to multiple substrate processing chambers in substrate processing systems and methods in accordance with aspects of this technology; and

FIG. 5 provides a schematic overhead view of cluster type substrate processing systems and methods in accordance with additional aspects of this technology.

It will be appreciated that elements in the figures are illustrated for simplicity and clarity and have not necessarily been drawn to scale and/or with full detail. For example, the relative size of some of the elements in the figures may be exaggerated relative to other elements to help improve understanding of illustrated embodiments of the present disclosure.

### DETAILED DESCRIPTION

Reference now will be made to the drawings wherein like reference numerals identify similar structural features or aspects of the subject disclosure.

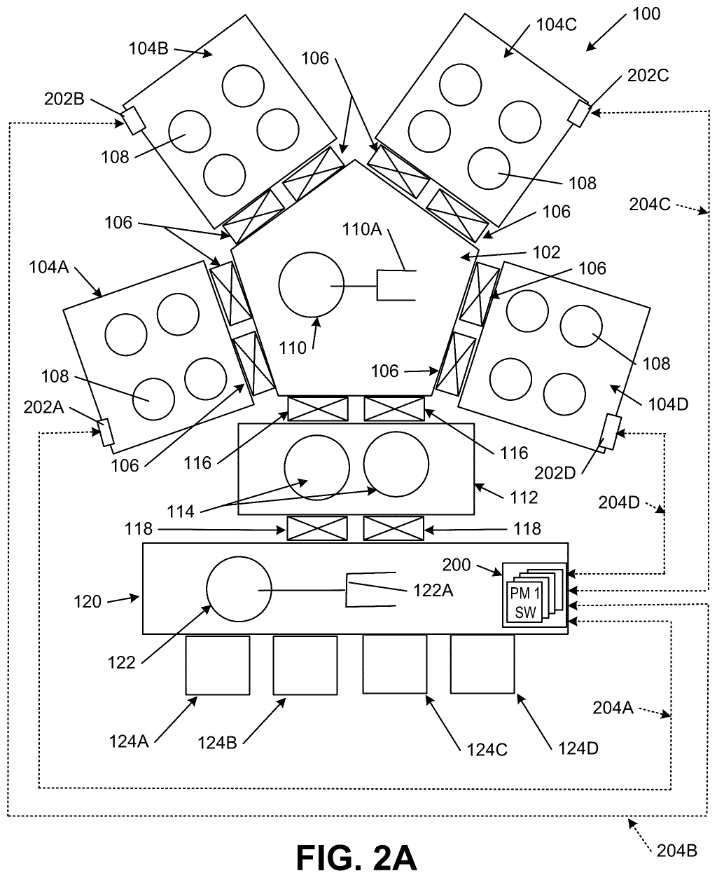

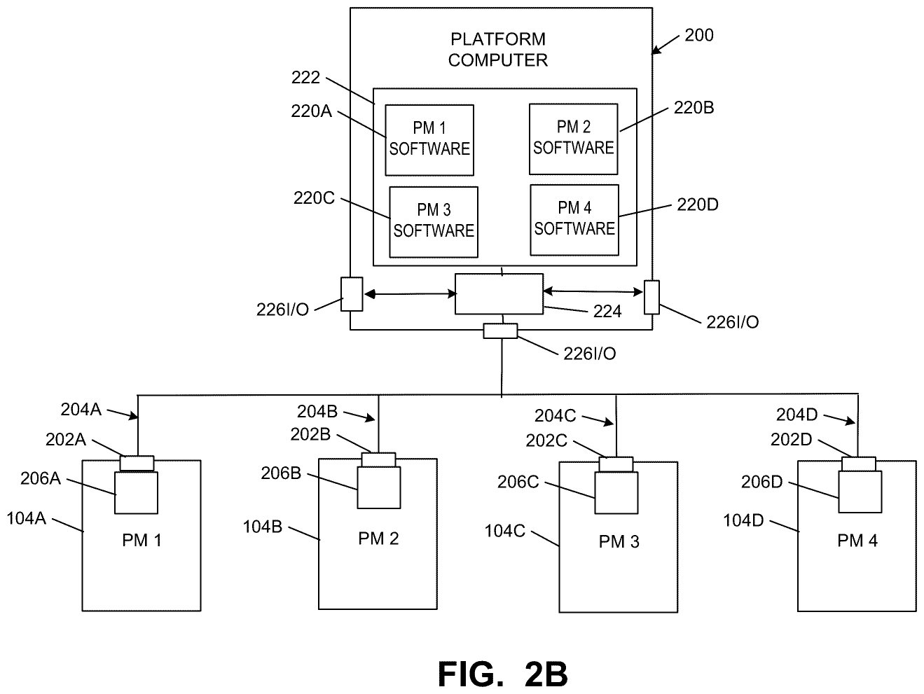

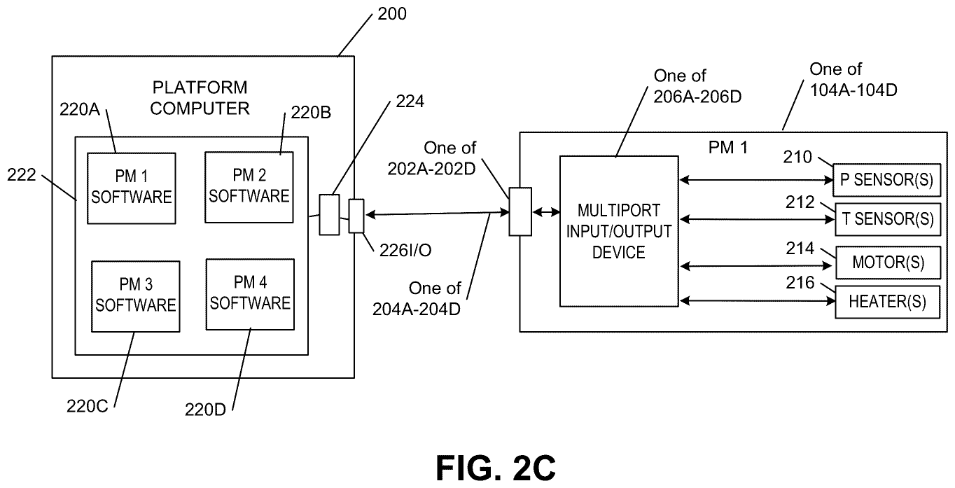

As noted above, material layers are commonly deposited onto substrates during fabrication of semiconductor devices, such as during fabrication of integrated circuits and electronic devices. FIG. 2A schematically illustrates a top view of a “cluster type” substrate processing system 100 in accordance with some examples of this technology. This example substrate processing system 100 includes a substrate handling chamber 102 that operatively connects with one to four substrate processing chambers 104A-104D via gate valves 106. Each substrate processing chamber 104A-104D includes one or more substrate supports and is equipped to receive a substrate on the substrate support 108 and hold the substrate during processing (e.g., during material layer deposition as described above, during etching processes, etc.). FIG. 2A shows each substrate processing chamber 104A-104D including four substrate supports 108 onto which substrates can be placed during processing. More or fewer substrates supports 108 may be provided in each substrate processing chamber 104A-104D (e.g., the substrate processing chambers 104A-104D may be dual chamber modules (DCM) or quad chamber modules (QCM)). Substrate processing chambers 104A-104D in accordance with some examples of this technology may include another four substrate supports 108 located vertically beneath the four substrate supports 108 shown in the top view of FIG. 2A. Each of the substrate processing chambers 104A-104D may have the same structures or one or more of the substrate processing chambers 104A-104D may have a different structure from other substrate processing chambers 104A-104D present.

The substrate handling chamber 102 includes robotic arm 110 used to move substrates into and out of the various substrate processing chambers 104A-104D through the gate valves 106. In use, a gate valve 106 is opened, an end effector 110A of the robotic arm 110 extends through the open gate valve 106 to insert a substrate into or remove a substrate from an interior chamber of the substrate processing chamber 104A-104D (e.g., placing a substrate on or taking a substrate off a substrate support 108 within the substrate processing chamber 104A-104D). Once the robotic arm 110 is retracted from the substrate processing chamber 104A-104D, the gate valve 106 is closed, thereby sealing the substrate processing chamber 104A-104D from the substrate handling chamber 102. Then, other desired actions can take place in the substrate processing chamber 104A-104D (e.g., material layer deposition, etching, etc.) and/or the substrate handling chamber 102.

FIG. 2A further shows that this example substrate processing system 100 includes a load-lock module 112. The load-lock module 112 is connected with the substrate handling chamber 102 by one or more gate valves 116. The load-lock module 112 includes substrate holding components 114 (e.g., “setplates”) for holding substrates on the way into the substrate handling chamber 102 for further processing and on the way out of the substrate handling chamber 102 (after processing is complete). The end effector 110A of robotic arm 110 moves through the gate valve 116 (when opened) to move substrates from the load-lock module 112 into the substrate handling chamber 102 (for layer deposition, etching, and/or other processing) and from the substrate handling chamber 102 into the load-lock module 112 (after processing is completed). The load-lock module 112 and gate valve(s) 116 keep the substrates isolated from the environment of the substrate handling chamber 102 until the conditions (e.g., temperature, pressure, content of atmosphere, etc.) within the substrate handling chamber 102 are ready for the substrate(s) to be inserted, e.g., while waiting for all gate valves 106 to be closed.

The load-lock module 112 further is coupled with an equipment front end module 120 via one or more additional gate valves 118. The equipment front end module 120 includes a robotic arm 122. The end effector 122A of that robotic arm 122 moves through the gate valve(s) 118 (when opened) to move substrates from the equipment front end module 120 into the load-lock module 112 (for layer deposition, etching, and/or other processing) and from the load-lock module 112 into the equipment front end module 120 (after processing is completed). The robotic arm 122 of the equipment front end module 120 also picks up new substrates for processing from one of the load ports 124A-124D and returns processed substrates to one of the load ports 124A-124D, e.g., to be transported to another location for further processing or other action.

FIGS. 2A-2C further show features of a platform computer 200 in accordance with some examples of this technology. FIG. 2A generally shows the platform computer 200 and its connections to input/output ports 202A-202D provided on substrate processing chambers 104A-104D, respectively, while FIGS. 2B and 2C show additional details about these connections and the architecture. As shown in FIG. 2A, the platform computer 200 is located remote from but in electronic communication with the substrate processing chambers 104A-104D via communications connections (e.g., cables 204A-204D, respectively). While FIG. 2A shows platform computer 200 housed with the equipment front end module 120, it could be provided as part of one of the other components (e.g., with the substrate handling chamber 102, the load-lock module 112, etc.), and/or it could be provided as a separate standalone component or at a separate workstation.

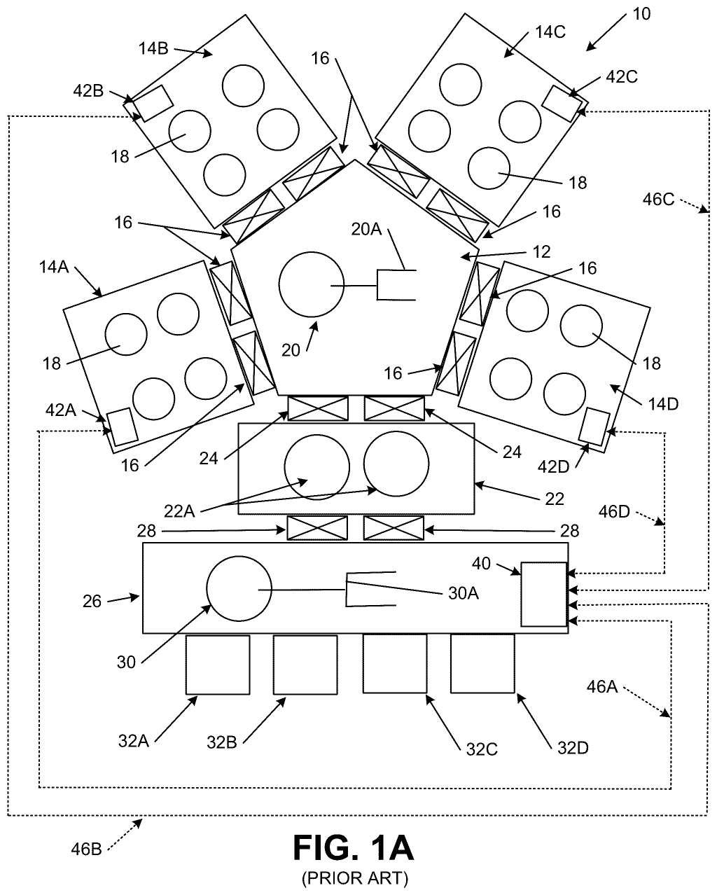

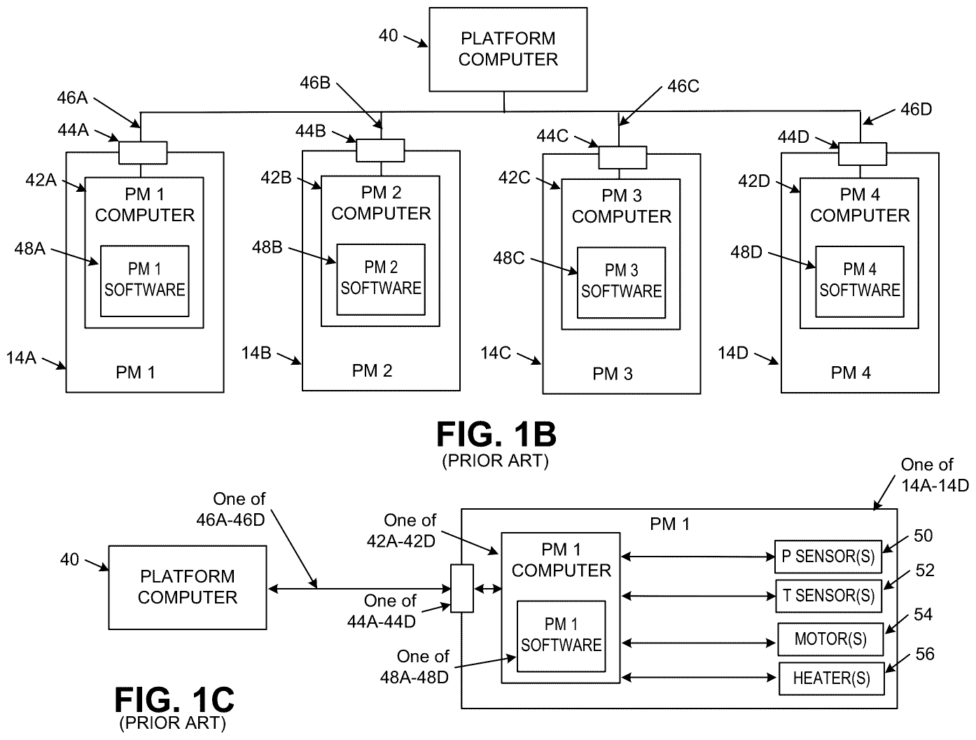

Rather than providing individual, dedicated computers 42A-42D with each substrate processing chamber 14A-14D as described above in conjunction with FIGS. 1A-1C, substrate processing systems 100 and methods in accordance with aspects of the present technology eliminate those separate, individual, dedicated computers 42A-42D and place (store) process module software 220A-220D in memory 222 provided in (or accessible by) the platform computer 200. Further, the separate, individual, dedicated computers 42A-42D of FIGS. 1A-1C may be eliminated in favor of one or more (relatively simple and inexpensive) multiport input/output devices 206A-206D associated with and provided at each substrate processing chamber 104A-104D, as shown in FIGS. 2B and 2C. The platform computer 200 may include one or more microprocessors 224, one or more input/output ports 226I/O (e.g., for wired and/or wireless communications), and/or other computer hardware and/or software components), and/or it may constitute a conventional computer of the types known and used in the art (and commercially available). In some examples of this technology, platform computer 200 will comprise server grade hardware of the type used to operate commercial systems.

Thus, the substrate processing chambers 104A-104D in substrate processing systems 100 and methods in accordance with aspects of the present technology will not include a personal computer storing and/or operating process module software for controlling operation of that substrate processing chamber 104A-104D. Rather, in accordance with aspects of this technology, process module software 220A-220D for each substrate processing chamber 104A-104D will be provided in the platform computer 200. Further, the platform computer 200 (located remote from the substrate processing chambers 104A-104D, e.g., at the equipment front end module 120 or load-lock module 112) will process incoming data (e.g., from sensors and equipment in the substrate processing chambers 104A-104D and from other sources) and generate output (using process module software 220A-220D) used to control equipment in and associated with the substrate processing chambers 104A-104D. In this manner, the platform computer 200 and the process module software 220A-220D running thereon will virtually (and/or remotely) control operation of the substrate processing chambers 104A-104D.

In the example systems and methods illustrated in FIGS. 2A-2C, cables 204A-204D (e.g., Ethernet cables) or other suitable wired or wireless connections connect the platform computer 200 with the input/output ports 202A-202D provided at substrate processing chambers 104A-104D, respectively. The input/output ports 202A-202D may connect with an input/output port and/or may constitute an input/output port of a respective multiport input/output device 206A-206D provided with each of the substrate processing chambers 104A-104D, respectively. The multiport input/output device 206A-206D may comprise an Ethernet switch (e.g., an 8-port Ethernet switch) or other device capable of routing data and/or electronic signals between one component and another component, e.g., between the platform computer 200 and one or more components provided within the individual substrate processing chamber 104A-104D (described below).

Multiport input/output devices 206A-206D of this illustrated example are further connected with one or more pressure sensors 210 (e.g., for measuring pressure in the interior chamber of the respective substrate processing chamber 104A-104D), one or more temperature sensors 212 (e.g., for measuring temperature in the interior chamber of the respective substrate processing chamber 104A-104D), one or more motors 214 (e.g., for opening or closing a gate valve 106, for activating a vacuum pump, for operating a gas supply pump or source, for rotating a substrate support, etc.), and one or more heating elements 216 (e.g., for changing temperature within the interior chamber of the respective substrate processing chamber 104A-104D). Multiport input/output device(s) 206A-206D may be connected to additional and/or other equipment associated with the respective substrate processing chamber 104A-104D.

With the connections and configurations illustrated in FIG. 2C, the process module software 220A-220D may be configured for receiving data from and/or relating to, transmitting data to, and/or operating a respective substrate processing chamber 104A-104D and/or the components associated with that respective substrate processing chamber 104A-104D. As some more specific examples, with the connections and configurations illustrated in FIG. 2C: (a) the platform computer 200 (and the process module software 220A-220D contained thereon) may send signals (e.g., data) through one of the cables 204A-204D, one of the input/output ports 202A-202D, and one of the multiport input/output devices 206A-206D to control and/or operate any one or more of the pressure sensor(s) 210, the temperature sensor(s) 212, the motor(s) 214, and/or the heating element(s) 216 associated with that substrate processing chamber 104A-104D; and/or (b) any one or more of the pressure sensor(s) 210, the temperature sensor(s) 212, the motor(s) 214, and/or the heating element(s) 216 associated with an individual substrate processing chamber 104A-104D may send (transmit) signals (e.g., data) through the multiport input/output devices 206A-206D, one of input/output ports 202A-202D, and one of the cables 204A-204D to the platform computer 200 (e.g., for use by the process module software 220A-220D associated with the substrate processing chamber 104A-104D transmitting the signals). The signals (e.g., data) received by the platform computer 200 may be used by the respective process module software 220A-220D to further control equipment and operation of the equipment in the respective substrate processing chamber 104A-104D. Thus, in this illustrated example: (a) process module software 220A in platform computer 200 is used to control operation of substrate processing chamber 104A; (b) process module software 220B in platform computer 200 is used to control operation of substrate processing chamber 104B; (c) process module software 220C in platform computer 200 is used to control operation of substrate processing chamber 104C; and (d) process module software 220D in platform computer 200 is used to control operation of substrate processing chamber 104D.

By eliminating the separate, individual, dedicated computers 42A-42D of FIGS. 1A-1C in favor of the remote and virtual architecture of the type shown in FIGS. 2A-2C, various advantages can be realized. For example, the costs for the individual computers, software licenses, and supporting equipment within the substrate processing chambers 104A-104D can be reduced or eliminated. Eliminating the separate, individual, dedicated computers 42A-42D of FIGS. 1A-1C also eliminates the need to maintain the operating systems, antivirus software, and/or application programs resident on those computers 42A-42D. Also, providing the process module software 220A-220D for the individual substrate processing chambers 104A-104D on the platform computer 200 retains all the necessary functionality provided by the eliminated computers 42A-42D of FIGS. 1A-1C and may provide this functionality on reliable, server grade hardware providing the platform computer 200.

As other potential advantages of the present technology of the type shown in FIGS. 2A-2C, the ability to interact with the process module software 220A-220D at the platform computer 200 location may limit (or eliminate) delays that could otherwise occur due to platform bus bandwidth constraints, such as can be the case when a user needs to access or transfer a relatively large log file (e.g., a precursor valve open/close cycling during deposition using an atomic layer deposition (“ALD”) technique), thereby improving reliability of the substrate processing system 100.

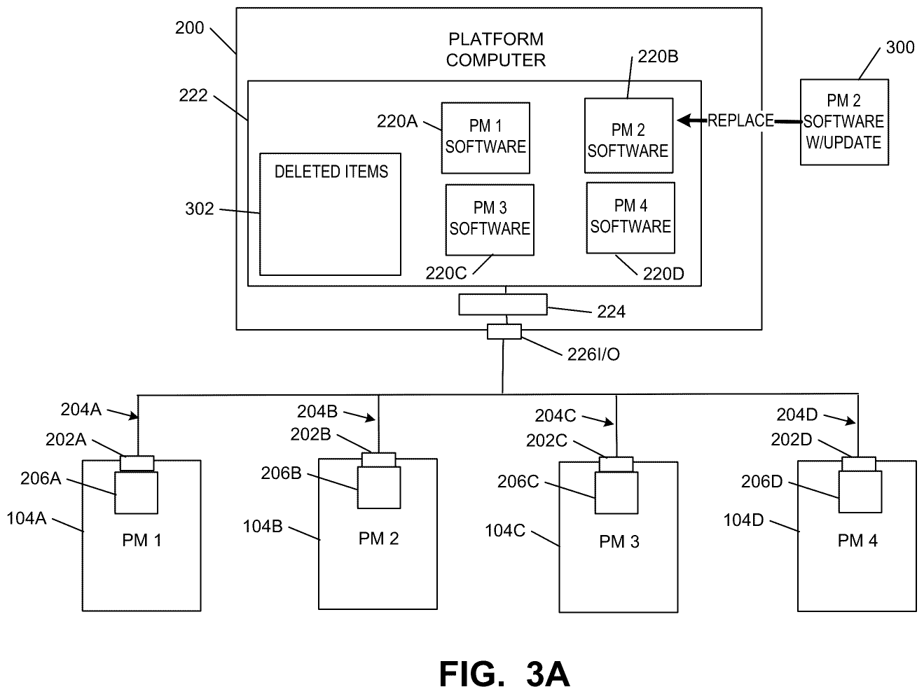

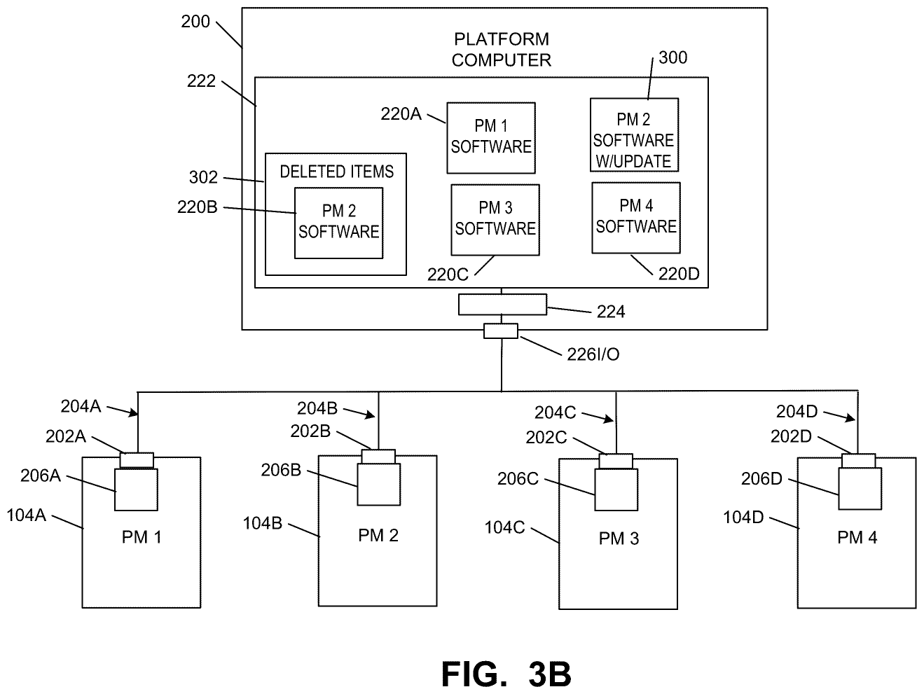

FIGS. 3A and 3B illustrate some example method features and aspects of this technology. Where the same reference numbers are used in FIGS. 3A and 3B as used in FIGS. 2A-2C, the same or similar parts are being referenced, and much of the overlapping description may be omitted.

FIG. 3A illustrates connection and operation of a substrate processing system in accordance with some examples of this technology (e.g., substrate processing system 100) at a first time period. At this time: (a) operating instructions generated (at least in part) by process module software 220A in platform computer 200 are used to control operation of substrate processing chamber 104A; (b) operating instructions generated (at least in part) by process module software 220B in platform computer 200 are used to control operation of substrate processing chamber 104B; (c) operating instructions generated (at least in part) by process module software 220C in platform computer 200 are used to control operation of substrate processing chamber 104C; and (d) operating instructions generated (at least in part) by process module software 220D in platform computer 200 are used to control operation of substrate processing chamber 104D.

Eventually, a need may arise in which at least a portion of the process module software 220A-220D for one of the substrate processing chambers 104A-104D may need to be changed. This may occur, for example, to apply an update to the process module software 220A-220D, to virus scan the process module software 220A-220D, to eliminate a virus threat from the process module software 220A-220D, etc. As shown in the example of FIG. 3A, first “replacement” process module software 300 may be created. The replacement process module software 300 may be created directly on the platform computer 200 and/or it may be introduced into the platform computer 200 (e.g., via an input/output port, such as from a downloaded file; from a USB drive, a disk, or other removable storage device; etc.). The replacement process module software 300 of the specific example of FIG. 3A is intended to replace all or just a portion of the code for the existing process module software 220B (e.g., providing an “update” to one or more portions of the software code of process module software 220B).

Once created, the replacement process module software 300 may be stored in the memory 222 of the platform computer 200. This storage may take place simultaneously with replacement, deletion, and/or overwriting of at least some (and optionally all) of prior process module software 220B in the memory 222 with replacement process module software 300. Thus, as shown in FIG. 3B: (a) the replacement process module software 300 located in platform computer 200 memory 222 and/or (b) at least some portion (and optionally all) of the prior process module software 220B may be moved to a “deleted items” area or cache 302 of memory 222 (or simply completely deleted, overwritten, and/or partially overwritten). Once the replacement process module software 300 is in place, the corresponding substrate processing chamber (substrate processing chamber 104B in this specific example) will be controlled and operated using operating instructions generated (at least in part) by replacement process module software 300 stored in platform computer 200 memory 222.

Process module software 220A-220D update and/or replacement, e.g., of the types described above, may take place multiple times (e.g., as often as needed) on the process module software 220A-220D stored on platform computer 200. For example, one or more additional “replacement” actions may take place on replacement process module software 300 after it is stored and actively used on the platform computer 200. Additionally or alternatively, one or more additional “replacement” actions may take place for process module software 220A, 220C, and/or 220D stored and actively used on the platform computer 200.

Advantageously, in at least some examples of this technology, replacement steps of the types described above in conjunction with FIGS. 3A and 3B may take place while the associated substrate processing chamber (substrate processing chamber 104B in the example described above in conjunction with FIGS. 3A and 3B) is actively processing one or more substrates, without interrupting processing of substrates anywhere in the substrate processing system 100, and/or without shutting down operation of the associated substrate processing chamber 104B. Avoiding the need to interrupt processing of substrates anywhere in the substrate processing system 100 and/or avoiding the need to shut down operation of the associated substrate processing chamber 104B can have significant advantages, as significant downtime and costs may be involved in cooling down the substrate processing chamber 104B, making the necessary changes, reheating the substrate processing chamber, recalibrating and/or requalifying the substrate processing chamber 104B operations, etc.

As some more specific examples of this technology, the replacement action may be scheduled by the platform computer 200 to take place during a time period when the associated substrate processing chamber 104B is involved in an activity that can be expected to take more time than the software replacement/update should take (e.g., atmosphere purging activity, temperature ramp up activity, temperature ramp down activity, etc.). Additionally or alternatively, the replacement action may be scheduled by the platform computer 200 to take place during a time period when the associated substrate processing chamber 104B is between operation steps (e.g., waiting for one or more new substrates to be inserted into the substrate processing chamber 104, waiting for substrate(s) to be removed, when substrate processing chamber 104B is inactive for any reason, etc.). Still additionally or alternatively, the “replacement” actions performed by the platform computer 200 could initiate processes that substantially instantaneously replace one active process module software component (e.g., 220B) with another (e.g., 300). For example, the replacement action may include: (a) transferring any relevant data from process module software 220B to initialize the replacement process module software 300 in background (if necessary) while process module software 220B actively controls substrate processing chamber 104B, and (b) after the replacement process module software 300 is fully initialized, changing the process calls, procedure calls, function calls, method calls, program calls, subprogram calls, routine calls, subroutine calls, and/or the like made by the platform computer 200 to call the replacement process module software 300 rather than the prior process module software 220B.

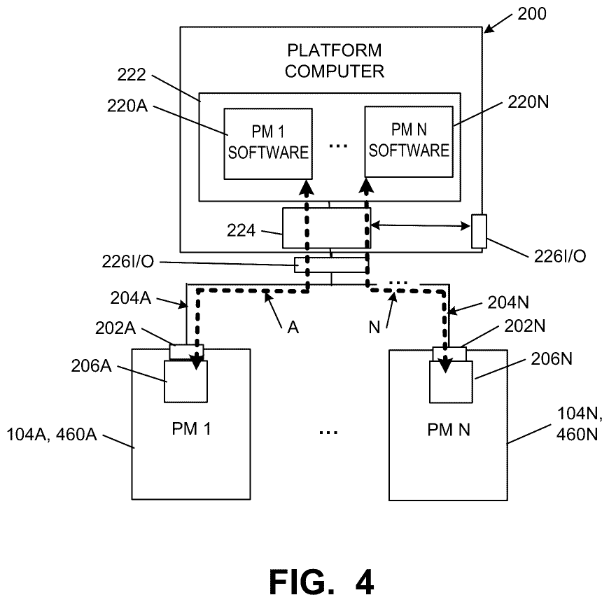

The examples above related to a substrate processing system 100 that included one substrate handling chamber 102 with up to four “clustered” substrate processing chambers 104A-104D. Other arrangements are possible. FIG. 4 provides a view of generic platform computer 200 and substrate processing system architecture in accordance with some examples of this technology in which a single, remote platform computer 200 includes process module software for “N” substrate handling chambers (e.g., 104A to 104N), where N can be any desired number (e.g., from 1 to 12). As shown in FIG. 4, connection and operation of substrate processing systems in accordance with examples of this technology may include: (a) using operating instructions generated (at least in part) by process module software 220A in platform computer 200 to control operation of substrate processing chamber 104A (see data transmission arrow A) up to (b) using operating instructions generated (at least in part) by process module software 220N in platform computer 200 to control operation of substrate processing chamber 104N (see data transmission arrow N), with each individual substrate processing chamber of the overall substrate processing system being operated from its own process module software (e.g., 220A to 220N) provided with the platform computer 200. The process module software 220A, . . . , 220N also can receive data back from its respective substrate processing chamber, e.g., using the same data transmission systems and connections. The individual substrate processing chambers 104A to 104N may include the more detailed structures and/or features and/or operate in the manners described above in conjunction with FIGS. 2A-3B.

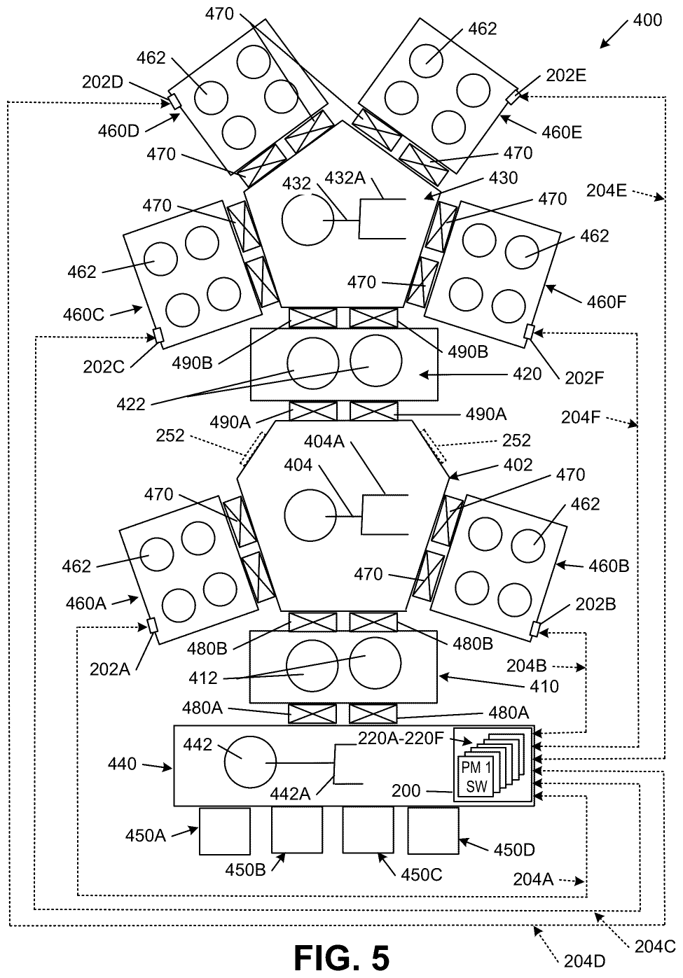

FIG. 5 schematically illustrates an overhead view of another example substrate processing system 400 in accordance with some examples of this technology (another “cluster” type semiconductor processing system), e.g., of the types generically illustrated in FIG. 4 in which “N” may be at least 6 or even up to 8. This substrate processing system 400 may be of the type described in U.S. Provisional Patent Appln. No. 63/524,272 filed Jun. 30, 2023 and entitled “Extended Substrate Processing Systems and Methods with Additional Processing Chamber Connectability.” U.S. Provisional Patent Appln. No. 63/524,272 is entirely incorporated herein by reference. Where the same reference number is used in FIG. 5 as used in any of FIGS. 2A-4, the same or similar part is being referenced, and much of the overlapping description may be omitted.

The substrate processing system 400 shown in FIG. 5 includes: (a) a first substrate handling chamber 402 (an “inboard” substrate handling chamber) including a first robotic arm 404 having an end effector 404A; (b) a first load-lock module 410 (an “inboard” load-lock module) connected at one edge or facet of the first substrate handling chamber 402; (c) a second load-lock module 420 (an “outboard” load-lock module) connected at the opposite edge or facet of the first substrate handling chamber 402; and (d) a second substrate handling chamber 430 (an “outboard” substrate handling chamber) including a second robotic arm 432 having an end effector 432A. The second load-lock module 420 extends between and connects the first substrate handling chamber 402 and the second substrate handling chamber 430. The first load-lock module 410 of this example also is connected with an equipment front end module 440 that includes a third robotic arm 442 having an end effector 442A. The equipment front end module 440 may include or connect with a nitrogen gas source for providing a nitrogen gas atmosphere within the equipment front end module 440. The equipment front end module 440 receives new substrates for processing into the substrate processing system 400 and discharges processed substrates from the substrate processing system 400 via one or more loading ports 450A-450D (moving the substrates between the loading port(s) 450A-450D and the first load-lock module 410 using the robotic arm 442). While four loading ports 450A-450D are shown in the example of FIG. 5, more or fewer loading ports may be provided in other examples of this technology.

Each of the first substrate handling chamber 402 and the second substrate handling chamber 430 is connected with (or connectable to) multiple substrate processing chambers 460A-460F (with two substrate processing chambers 460A and 460B connected with substrate handling chamber 402 and four substrate processing chambers 460C-460F connected with substrate handling chamber 430). Substrates are transferred into the substrate processing chambers 460A-460F where one or more layers of material are deposited onto a surface of the substrate and/or other desired substrate processing takes place. FIG. 5 shows each substrate processing chamber 460A-460F including four substrate supports 462 onto which substrates can be placed during processing. More or fewer substrates supports 462 may be provided in each substrate processing chamber 460A-460F (e.g., the substrate processing chambers 460A-460F may be dual chamber modules (DCM) or quad chamber modules (QCM)). Substrate processing chambers 460A-460F in accordance with some examples of this technology may include another four substrate supports 462 located vertically beneath the four substrate supports 462 shown in the top view of FIG. 5. Each of the substrate processing chambers 460A-460F may have the same structures or one or more of the substrate processing chambers 460A-460F may have a different structure from other of the substrate processing chambers 460A-460F present.

Each of the first substrate handling chamber 402 and the second substrate handling chamber 430 is connected with its respective substrate processing chambers 460A-460F via one or more gate valves 470. While two gate valves 470 are shown connecting substrate handling chambers 402, 430 with each of their respective substrate processing chambers 460A-460F, more or fewer gate valves 470 may be provided with each substrate processing chamber 460A-460F, in other examples of this technology. Substrate processing chambers 460A-460F in accordance with some examples of this technology may be connected with their respective substrate handling chamber 402, 430 by another two gate valves 470, e.g., located vertically beneath the two gate valves 470 shown in the top view of FIG. 5. When closed, the gate valves 470 sealingly separate the substrate handling chambers 402, 430 from their respective substrate processing chambers 460A-460F (so that independent atmospheric conditions may be maintained in each chamber). When open, the gate valves 470 provide an opening (e.g., a substrate transfer slot) through which the end effector 404A, 432A of a robotic arm 404, 432 can extend to move substrates into and out of the substrate processing chamber 460A-460F. The openings through the gate valves 470 align with substrate transfer slots provided in the substrate processing chambers 460A-460F and the substrate handling chambers 402, 430, to enable substrates to be moved between the substrate processing chambers 460A-460F and the substrate handling chambers 402, 430 through the gate valves 470. Each of gate valves 470 may have the same structure or one or more of the gate valves 470 may have a different structure from other gate valves 470 present.

One face of the first load-lock module 410 connects with the equipment front end module 440 by one or more gate valves 480A (two shown in FIG. 5), and the opposite face of the first load-lock module 410 connects with the first substrate handling chamber 402 by one or more gate valves 480B (two shown in FIG. 5). The first load-lock module 410 further includes one or more substrate supports 412 (two shown in FIG. 5, e.g., “setplates”) for holding substrates while they wait to be moved into the equipment front end module 440 or the first substrate handling chamber 402. When closed, the gate valves 480A, 480B sealingly separate the load-lock module 410 from the equipment front end module 440 and the substrate handling chamber 402 (so that independent atmospheric conditions may be maintained in each chamber). When open, the gate valves 480A provide an opening (e.g., a substrate transfer slot) through which the end effector 442A of robotic arm 442 can extend to move substrates into and out of the equipment front end module 440. The openings through the gate valves 480A align with substrate transfer slots provided in the equipment front end module 440 and the first load-lock module 410 to enable substrates to be moved between the equipment front end module 440 and the first load-lock module 410 through gate valves 480A. When open, the gate valves 480B provide an opening (e.g., a substrate transfer slot) through which the end effector 404A of robotic arm 404 can extend to move substrates into and out of the substrate handling chamber 402. The openings through the gate valves 480B align with substrate transfer slots provided in the substrate handling chamber 402 and the first load-lock module 410 to enable substrates to be moved between the substrate handling chamber 402 and the first load-lock module 410 through gate valves 480B. Each of gate valves 480A, 480B may have the same structure or one or more of the gate valves 480A, 480B may have a different structure from other gate valves 470, 480A, 480B present.

In the substrate processing system 400 of FIG. 5, one face of the second load-lock module 420 connects with the first substrate handling chamber 402 by one or more gate valves 490A (two shown in FIG. 5), and the opposite face of the second load-lock module 420 connects with the second substrate handling chamber 430 by one or more gate valves 490B (two shown in FIG. 5). The second load-lock module 420 further includes one or more substrate supports 422 (two shown in FIG. 5, e.g., “setplates”) for holding substrates while they wait to be moved between the two substrate handling chambers 402, 430. When closed, the gate valves 490A, 490B sealingly separate the second load-lock module 420 from the two substrate handling chambers 402, 430 (so that independent atmospheric conditions may be maintained in each chamber). When open, the gate valves 490A provide an opening (e.g., a substrate transfer slot) through which the end effector 404A of robotic arm 404 can extend to move substrates into and out of the first substrate handling chamber 402. The openings through the gate valves 490A align with substrate transfer slots provided in the first substrate handling chamber 402 and the second load-lock module 420 to enable substrates to be moved between the substrate handling chamber 402 and the second load-lock module 420 through gate valves 490A. When open, the gate valves 490B provide an opening (e.g., a substrate transfer slot) through which the end effector 432A of robotic arm 432 can extend to move substrates into and out of the second substrate handling chamber 430. The openings through the gate valves 490B align with substrate transfer slots provided in the second substrate handling chamber 430 and the second load-lock module 420 to enable substrates to be moved between the second substrate handling chamber 430 and the second load-lock module 420 through gate valves 490B. Each of gate valves 490A, 490B may have the same structure or one or more of the gate valves 490A, 490B may have a different structure from other gate valves 490A, 490B present. Gate valves 490A and/or 490B also may have the same or different structures from gate valves 470, 480A, and/or 480B.

The first load-lock module 410 may have the same structure as the second load-lock module 420 and/or the first and second load-lock modules 410, 420 may be interchangeable (e.g., so that load-lock modules 410, 420 can switch positions and/or have a modular structure). In other examples, the first load-lock module 410 and the second load-lock module 420 may have different structures and/or may not be interchangeable (e.g., so that load-lock modules 410, 420 cannot switch positions in the substrate processing system 400). Either or both load-lock modules 410, 420 may be multi-station cooling capable and/or path through types.

As shown in broken lines in FIG. 5, two smaller facets of the first substrate handling chamber 402 may be equipped with at least one substrate transfer slot 252. The substrate transfer slot(s) 252, when present, may be sealed (e.g., by a removable seal plate) in substrate processing system 400 arrangements of the type shown in FIG. 5 where no substrate processing chamber 460 is attached to those facets. The substrate transfer slot(s) 252 in these facets also may be smaller than corresponding slots in the other facets of the first substrate handling chamber 402 and/or the second substrate handling chamber 430 (although transfer slot(s) 252 need not be smaller in all examples of this technology). Thus, these smaller facets may be connected to substrate processing chambers via additional gate valves, if desired (optionally, smaller substrate processing chambers).

FIG. 5 further shows that this example substrate processing system 400 includes a platform computer 200, e.g., of the types described above in conjunction with FIGS. 2A-4, including process module software 220A-220F for each of the substrate processing chambers 460A-460F. FIG. 5 generally shows the platform computer 200 and its connections to input/output ports 202A-202F provided on substrate processing chambers 460A-460F, respectively. As shown in FIG. 5, the platform computer 200 is located remote from but in electronic communication with the substrate processing chambers 460A-460F via communications connections (e.g., cables 204A-204F, respectively, such as Ethernet cables). While FIG. 5 shows platform computer 200 housed with the equipment front end module 440, it could be provided as part of one of the other components (e.g., with one of the substrate handling chambers 402, 430, one of the load-lock modules 410, 420, etc.), and/or it could be provided as a separate standalone component or at a separate workstation.

In the example systems and methods illustrated in FIG. 5, cables 204A-204F (e.g., Ethernet cables) or other suitable wired or wireless connections connect the platform computer 200 with the input/output ports 202A-202F provided at substrate processing chambers 460A-460F, respectively. The input/output ports 202A-202F may connect with an input/output port and/or may constitute an input/output port of a respective multiport input/output device provided with each of the substrate processing chambers 460A-460F, respectively. The multiport input/output devices included with the substrate processing chambers 460A-460F may be structured and/or function in any of the manners described above for multiport input/output devices 206A-206D in conjunction with FIGS. 2A-4. As some more specific examples, the multiport input/output devices 206A-206F included with the substrate processing chambers 460A-460F of FIG. 5 may comprise an Ethernet switch (e.g., an 8-port Ethernet switch) or other device capable of routing data and/or electronic signals between one component and another component, e.g., between the platform computer 200 and one or more components provided within the individual substrate processing chamber 460A-460F. Thus, the configuration and architecture of the substrate processing system 400 of FIG. 5 eliminates the need for separate, dedicated computers in the substrate processing chambers 460A-460F (and thus may provide some or all of the advantages described above with respect to FIGS. 2A-3B).

In other examples of this technology when one or two additional substrate processing chambers are provided at substrate transfer slot(s) 252 of substrate handling chamber 402, additional process module software (e.g., like 220A) may be provided in the platform computer 200 for operating those additional substrate processing chambers. More specifically, in such systems, the “N” in FIG. 4 may equal 7 or 8. The additional substrate processing chamber(s) at substrate transfer slot(s) 252, when present, may have the same connections and structures as described above for the other substrate processing chambers 104A-104D, 460A-460F (e.g., an input/output port like port 202A, a multiport input/output device like 206A, a cable or other connection like 204A, etc.).

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A substrate processing system, comprising:
a first substrate handling chamber including a first robotic arm;
a first substrate processing chamber coupled with the first substrate handling chamber via a first gate valve, wherein a portion of the first robotic arm is configured to extend through the first gate valve and into the first substrate processing chamber to move substrates into and out of the first substrate processing chamber;
a second substrate processing chamber coupled with the first substrate handling chamber via a second gate valve, wherein the portion of the first robotic arm is configured to extend through the second gate valve and into the second substrate processing chamber to move substrates into and out of the second substrate processing chamber; and
a platform computer located remote from and in electronic communication with the first substrate processing chamber and the second substrate processing chamber, the platform computer: (a) including memory storing first process module software for operating the first substrate processing chamber and second process module software for operating the second substrate processing chamber, (b) transmitting signals for operating the first substrate processing chamber based on data generated by the first process module software, and (c) transmitting signals for operating the second substrate processing chamber based on data generated by the second process module software.

2. The substrate processing system according to claim 1, further comprising:
a third substrate processing chamber coupled with the first substrate handling chamber via a third gate valve, wherein the portion of the first robotic arm is configured to extend through the third gate valve and into the third substrate processing chamber to move substrates into and out of the third substrate processing chamber, wherein the platform computer is located remote from and in electronic communication with the third substrate processing chamber, wherein the memory of the platform computer further stores third process module software for operating the third substrate processing chamber, and wherein the platform computer further transmits signals for operating the third substrate processing chamber based on data generated by the third process module software.

3. The substrate processing system according to claim 2, further comprising:
a fourth substrate processing chamber coupled with the first substrate handling chamber via a fourth gate valve, wherein the portion of the first robotic arm is configured to extend through the fourth gate valve and into the fourth substrate processing chamber to move substrates into and out of the fourth substrate processing chamber, wherein the platform computer is located remote from and in electronic communication with the fourth substrate processing chamber, wherein the memory of the platform computer further stores fourth process module software for operating the fourth substrate processing chamber, and wherein the platform computer further transmits signals for operating the fourth substrate processing chamber based on data generated by the fourth process module software.

4. The substrate processing system according to claim 3, further comprising:
a second substrate handling chamber including a second robotic arm; and
a fifth substrate processing chamber coupled with the second substrate handling chamber via a fifth gate valve, wherein a portion of the second robotic arm is configured to extend through the fifth gate valve and into the fifth substrate processing chamber to move substrates into and out of the fifth substrate processing chamber, wherein the platform computer is located remote from and in electronic communication with the fifth substrate processing chamber, wherein the memory of the platform computer further stores fifth process module software for operating the fifth substrate processing chamber, and wherein the platform computer further transmits signals for operating the fifth substrate processing chamber based on data generated by the fifth process module software.

5. The substrate processing system according to claim 4, further comprising:
a sixth substrate processing chamber coupled with the second substrate handling chamber via a sixth gate valve, wherein the portion of the second robotic arm is configured to extend through the sixth gate valve and into the sixth substrate processing chamber to move substrates into and out of the sixth substrate processing chamber, wherein the platform computer is located remote from and in electronic communication with the sixth substrate processing chamber, wherein the memory of the platform computer further stores sixth process module software for operating the sixth substrate processing chamber, and wherein the platform computer further transmits signals for operating the sixth substrate processing chamber based on data generated by the sixth process module software.

6. The substrate processing system according to claim 4, further comprising:
a load lock module connecting the first substrate handling chamber and the second substrate handling chamber, wherein the load lock module is configured to hold substrates moving between the first substrate handling chamber and the second substrate handling chamber.

7. The substrate processing system according to claim 1, further comprising:
a second substrate handling chamber including a second robotic arm; and
a third substrate processing chamber coupled with the second substrate handling chamber via a third gate valve, wherein a portion of the second robotic arm is configured to extend through the third gate valve and into the third substrate processing chamber to move substrates into and out of the third substrate processing chamber, wherein the platform computer is located remote from and in electronic communication with the third substrate processing chamber, wherein the memory of the platform computer further stores third process module software for operating the third substrate processing chamber, and wherein the platform computer further transmits signals for operating the third substrate processing chamber based on data generated by the third process module software.

8. The substrate processing system according to claim 7, further comprising:
a load lock module connecting the first substrate handling chamber and the second substrate handling chamber, wherein the load lock module is configured to hold substrates moving between the first substrate handling chamber and the second substrate handling chamber.

9. A substrate processing system, comprising:
a first substrate handling chamber including a first robotic arm;
a first substrate processing chamber coupled with the first substrate handling chamber via a first gate valve, wherein a portion of the first robotic arm is configured to extend through the first gate valve and into the first substrate processing chamber to move substrates into and out of the first substrate processing chamber;
a second substrate processing chamber coupled with the first substrate handling chamber via a second gate valve, wherein the portion of the first robotic arm is configured to extend through the second gate valve and into the second substrate processing chamber to move substrates into and out of the second substrate processing chamber;
a front end module configured to receive unprocessed substrates for processing and to hold processed substrates prior to removal from the substrate processing system;
a first load lock module connecting the front end module and the first substrate handling chamber, wherein the first load lock module is configured to hold substrates moving between the front end module and the first substrate handling chamber; and
a platform computer provided with the front end module or the first load lock module, the platform computer being located remote from and in electronic communication with the first substrate processing chamber and the second substrate processing chamber, the platform computer: (a) including memory storing first process module software for operating the first substrate processing chamber and second process module software for operating the second substrate processing chamber, (b) transmitting signals for operating the first substrate processing chamber based on data generated by the first process module software, and (c) transmitting signals for operating the second substrate processing chamber based on data generated by the second process module software.

10. The substrate processing system according to claim 9, further comprising:
a second substrate handling chamber including a second robotic arm;
a second load lock module connecting the first substrate handling chamber and the second substrate handling chamber, wherein the second load lock module is configured to hold substrates moving between the first substrate handling chamber and the second substrate handling chamber; and
a third substrate processing chamber coupled with the second substrate handling chamber via a third gate valve, wherein a portion of the second robotic arm is configured to extend through the third gate valve and into the third substrate processing chamber to move substrates into and out of the third substrate processing chamber, wherein the platform computer is located remote from and in electronic communication with the third substrate processing chamber, wherein the memory of the platform computer further stores third process module software for operating the third substrate processing chamber, and wherein the platform computer further transmits signals for operating the third substrate processing chamber based on data generated by the third process module software.

11. The substrate processing system according to claim 9, further comprising:
a second substrate handling chamber including a second robotic arm;
a second load lock module connecting the first substrate handling chamber and the second substrate handling chamber, wherein the second load lock module is configured to hold substrates moving between the first substrate handling chamber and the second substrate handling chamber; and
a plurality of additional substrate processing chambers coupled with the second substrate handling chamber, wherein a portion of the second robotic arm is configured to extend into the plurality of additional substrate processing chambers to move substrates into and out of the plurality of additional substrate processing chambers, wherein the platform computer is located remote from and in electronic communication with the plurality of additional substrate processing chambers, wherein the memory of the platform computer further stores process module software for operating each of the plurality of additional substrate processing chambers, and wherein the platform computer further transmits signals for operating the plurality of additional substrate processing chambers based on data generated by the process module software for the plurality of additional substrate processing chambers.

12. The substrate processing system according to claim 9, further comprising:
a second substrate handling chamber including a second robotic arm;
a second load lock module connecting the first substrate handling chamber and the second substrate handling chamber, wherein the second load lock module is configured to hold substrates moving between the first substrate handling chamber and the second substrate handling chamber; and
a plurality of additional substrate processing chambers coupled with the second substrate handling chamber, wherein a portion of the second robotic arm is configured to extend into the plurality of additional substrate processing chambers to move substrates into and out of the plurality of additional substrate processing chambers, wherein the platform computer is located remote from and in electronic communication with the plurality of additional substrate processing chambers, wherein the memory of the platform computer further stores separate process module software for operating each of the plurality of additional substrate processing chambers, and wherein the platform computer further transmits signals for operating the plurality of additional substrate processing chambers based on data generated by the process module software for the respective plurality of additional substrate processing chambers.

13. The substrate processing system according to claim 9, further comprising:
a plurality of additional substrate processing chambers coupled with the first substrate handling chamber, wherein the portion of the first robotic arm is configured to extend into the plurality of additional substrate processing chambers to move substrates into and out of the plurality of additional substrate processing chambers, wherein the platform computer is located remote from and in electronic communication with the plurality of additional substrate processing chambers, wherein the memory of the platform computer further stores process module software for operating each of the plurality of additional substrate processing chambers, and wherein the platform computer further transmits signals for operating the plurality of additional substrate processing chambers based on data generated by the process module software for the respective plurality of additional substrate processing chambers.

14. A method of operating a substrate processing system, the method comprising:
operating a first substrate processing chamber using first operating instructions generated by first process module software stored in memory on a platform computer located remote from and in electronic communication with the first substrate processing chamber;
operating a second substrate processing chamber using second operating instructions generated by second process module software stored in the memory on the platform computer located remote from and in electronic communication with the second substrate processing chamber;
creating first replacement process module software;
storing the first replacement process module software in the memory of the platform computer;
replacing the first process module software with the first replacement process module software; and
operating the first substrate processing chamber using operating instructions generated by the first replacement process module software stored in the memory on the platform computer.

15. The method according to claim 14, further comprising:
creating second replacement process module software;
storing the second replacement process module software in the memory of the platform computer;
replacing the second process module software with the second replacement process module software; and
operating the second substrate processing chamber using operating instructions generated by the second replacement process module software stored in the memory on the platform computer.

16. The method according to claim 14, further comprising:
creating second replacement process module software;
storing the second replacement process module software in the memory of the platform computer;
replacing the first replacement process module software with the second replacement process module software; and
operating the first substrate processing chamber using operating instructions generated by the second replacement process module software stored in the memory on the platform computer.

17. The method according to claim 14, wherein the step of replacing the first process module software with the first replacement process module software occurs while the first substrate processing chamber is processing one or more substrates and without interrupting processing of the one or more substrates.

18. The method according to claim 14, wherein the step of replacing the first process module software with the first replacement process module software occurs without shutting down operation of the first substrate processing chamber.

19. The method according to claim 14, wherein the first replacement process module software comprises a software upgrade from the first process module software.

20. The method according to claim 14, further comprising:
operating one or more additional substrate processing chambers using additional operating instructions generated by one or more additional process module software components stored in the memory on the platform computer located remote from and in electronic communication with the one or more additional substrate processing chambers;
creating an additional replacement process module software component;
storing the additional replacement process module software component in the memory of the platform computer;
replacing one of the additional process module software components with the additional replacement process module software component; and
operating a specific additional substrate processing chamber associated with the additional process module software component that was replaced by the additional replacement process module software component using operating instructions generated by the additional replacement process module software component stored in the memory on the platform computer.
